(19) United States
(12) Patent Application Publication
(10) Pub. No.: US 2022/0108742 A1
(43) Pub. Date: Apr. 7, 2022

(54) DIFFERENTIAL CHARGE SHARING FOR COMPUTE-IN-MEMORY (CIM) CELL

(71) Applicant: QUALCOMM Incorporated, San Diego, CA (US)

(72) Inventors: Xia LI, San Diego, CA (US); Zhongze WANG, San Diego, CA (US); Xiaonan CHEN, San Diego, CA (US); Xiaochun ZHU, San Diego, CA (US)

(21) Appl. No.: 17/062,148

(22) Filed: Oct. 2, 2020

(51) Int. Cl. G11C 11/4094; G11C 11/4091; G11C 11/4099; G11C 11/404; G11C 5/06

(52) U.S. Cl. CPC G11C 11/4094; G11C 11/4091; G11C 5/06; G11C 11/4045; G11C 11/4099

(57) ABSTRACT

Certain aspects of the present disclosure provide a circuit for in-memory computation. The circuit generally includes a memory cell having a bit-line and a complementary bit-line, a first capacitive element coupled to the bit-line, a second capacitive element coupled to the complementary bit-line, a processing circuit, a first switch coupled between a first input of the processing circuit and the bit-line, and a second switch coupled between a second input of the processing circuit and the complementary bit-line

### BACKGROUND

### Field of the Disclosure

Certain aspects of the present disclosure generally relate to electronic components and, more particularly, to a compute-in-memory (CIM) cell.

### Description of Related Art

Static random-access memory (SRAM) is a type of memory that uses a flip-flop (FF) to store the value of each bit in a memory cell. In particular, an SRAM is a volatile memory in that the data stored in the memory is lost when the memory is not provided a supply voltage. In some implementations, an SRAM may use compute-in-memory (CIM) circuitry, allowing a logic operation to be performed on data stored in memory simultaneously during a read phase for the memory.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description” one will understand how the features of this disclosure provide a compute-in-memory (CIM) cell offering larger analog-to-digital conversion dynamic range and/or improved resolution, as well as increased energy efficiency.

Certain aspects of the present disclosure provide a circuit for in-memory computation. The circuit generally includes a memory cell having a bit-line and a complementary bit-line, a first capacitive element coupled to the bit-line, a second capacitive element coupled to the complementary bit-line, a processing circuit, a first switch coupled between a first input of the processing circuit and the bit-line, and a second switch coupled between a second input of the processing circuit and the complementary bit-line.

Certain aspects of the present disclosure provide a method for in-memory computation. The method generally includes storing charge on at least one of a first capacitive element or a second capacitive element based on a data value stored in a memory cell. The first capacitive element is coupled to a bit-line of the memory cell, and the second capacitive element is coupled to a complementary bit-line of the memory cell. The method also includes sensing, via a processing circuit, the charge stored on the at least one of the first capacitive element or the second capacitive element. A first switch is coupled between a first input of the processing circuit and the bit-line, and a second switch is coupled between a second input of the processing circuit and the complementary bit-line.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1 illustrates an example computation system having a computation array implemented for in-memory convolution computation, in accordance with certain aspects of the present disclosure.

FIGS. 2A, 2B, and 2C illustrate implementations of an example compute-in-memory (CIM) circuit, in accordance with certain aspects of the present disclosure.

FIG. 2D is a truth table associated with the CIM circuits of FIGS. 2A, 2B, and 2C, in accordance with certain aspects of the present disclosure.

FIGS. 3A, 3B, and 3C illustrate CIM circuits implemented with capacitive elements coupled between pass-gate (PG) switches and read bit lines, in accordance with certain aspects of the present disclosure.

FIG. 3D is a truth table associated with the CIM circuits of FIGS. 3A, 3B, and 3C, in accordance with certain aspects of the present disclosure.

FIG. 4 is a flow diagram of example operations for in-memory computation, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure relate to a compute-in-memory (CIM) cell implemented using charge sharing (CS) via capacitive elements. For example, the CIM cell may be implemented with a processing system that detects a differential voltage between a read bitline (RBL) and a complementary RBL (RBLB), providing a higher dynamic range with improved resolution for the processing system, as compared to conventional implementations where a single-ended voltage-sensing technique is used.

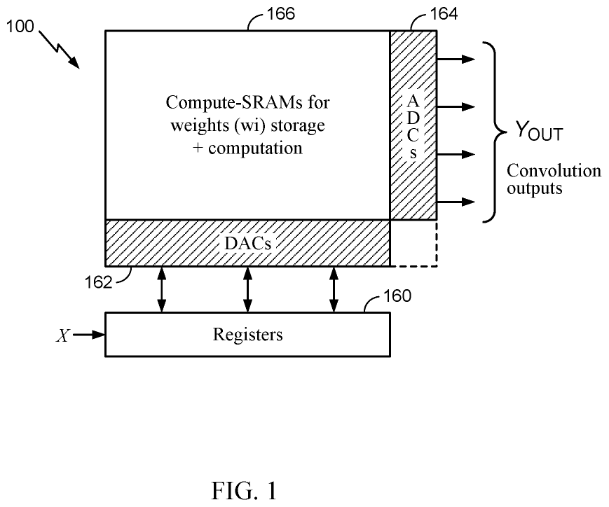

FIG. 1 illustrates an example computation system 100 having a computation array 166 implemented for in-memory convolution computation, in accordance with certain aspects of the present disclosure. The computation array 166 may include an array of static random-access memory (SRAM) memory cells, each implemented with computation circuitry using a CS technique, as described in more detail herein. Data (e.g., weight parameters for a neural network or other system) may be stored in the SRAM memory cells of the computation array 166. As illustrated, input data, labeled “X” in FIG. 1, may be input to registers 160. The input data may be provided to the computation circuitry via digital-to-analog converters (DACs) 162. The computation array 166 may perform in-memory convolution computation based on the input data and as a function of weights (wi) stored in the SRAM memory cells. The output of the computation may be input to analog-to-digital converters (ADCs) 164, which provide digital convolution outputs, labeled in FIG. 1 as “YOUT.”

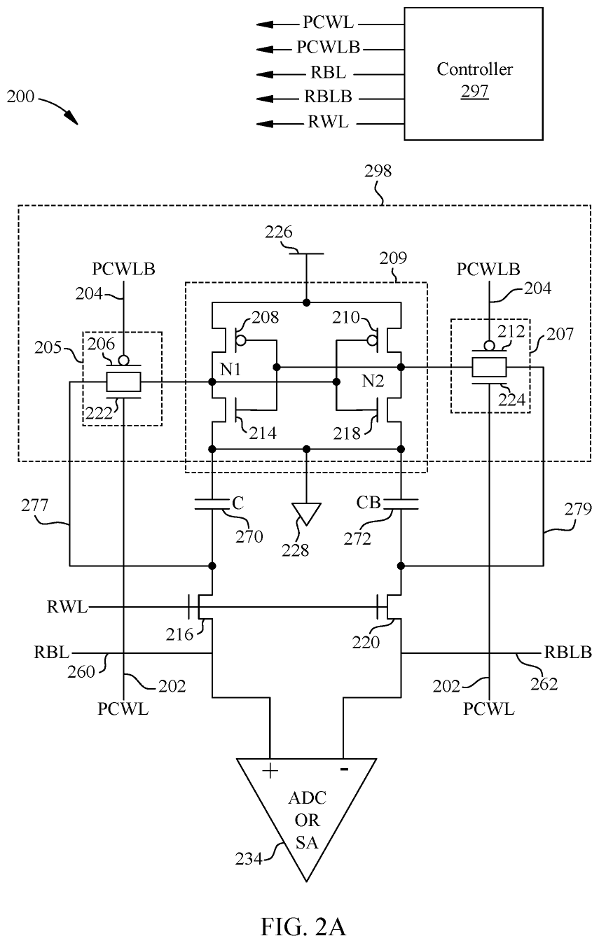

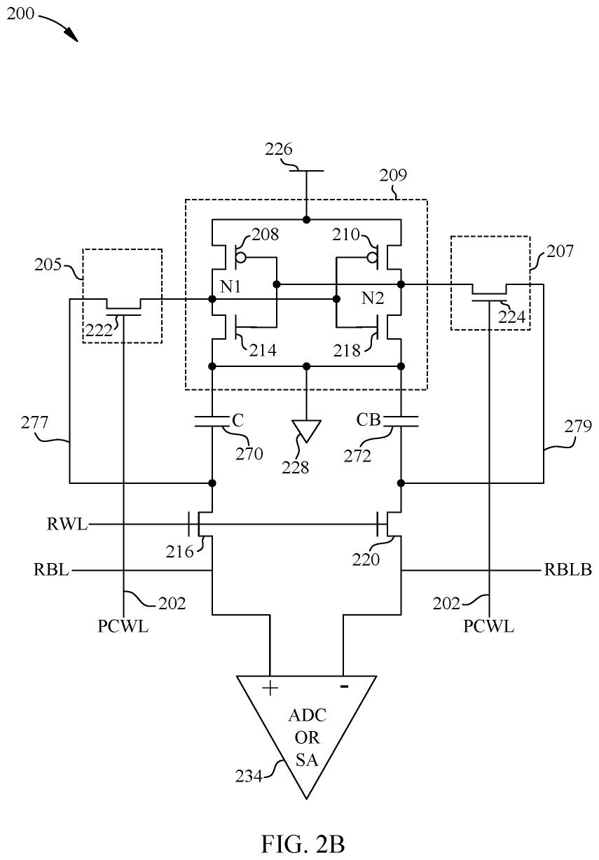

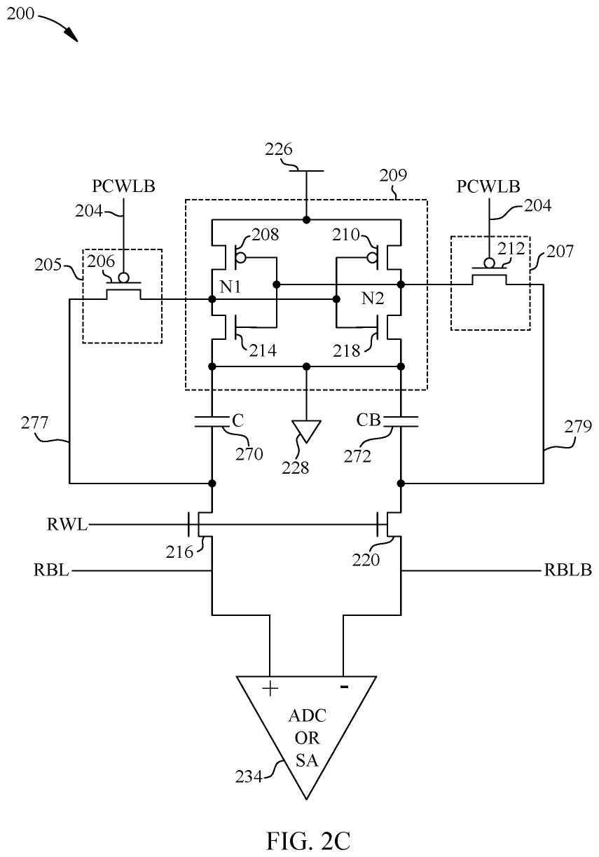

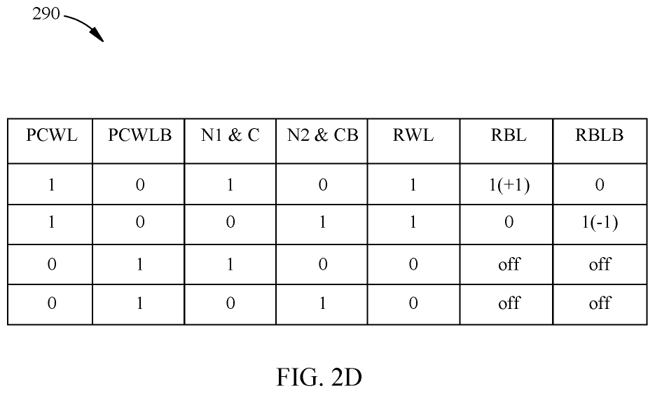

FIGS. 2A, 2B, and 2C illustrate implementations of an example CIM circuit 200, in accordance with certain aspects of the present disclosure. The CIM circuit 200 may be configured to perform an exclusive NOR (XNOR) operation or XOR operation. The XNOR operation is the logical complement of the XOR operation. The CIM circuit 200 may include a static random access memory (SRAM) memory cell 298 implemented using a pass-charge word line (PCWL) 202 and an inverse PCWL (PCWLB) 204. The PCWL 202 is coupled to control inputs of pass-gate (PG) switches 205, 207 for selectively coupling respective bit lines (bit line (BL) 277, complementary BL (BLB) 279) to respective nodes N1, N2 (also referred to as an output node and a complementary output node, respectively) of a flip-flop (FF) 209. As illustrated in FIG. 2A, the switch 205 and the switch 207 may each be implemented using a transmission gate. For example, the switch 205 may include a p-type metal-oxide-semiconductor (PMOS) transistor 206 in parallel with an n-type metal-oxide-semiconductor (NMOS) transistor 222, and the switch 207 may include a PMOS transistor 212 in parallel with an NMOS transistor 224, as illustrated. In certain aspects, the switches 205, 207 may each be implemented using NMOS transistors 222, 224, respectively, as illustrated in FIG. 2B. In some aspects, the switches 205, 207 may each be implemented using PMOS transistors 206, 212, respectively, as illustrated in FIG. 2C.

As illustrated, the FF 209 is coupled between a voltage rail (Vdd) 226 and a reference potential node 228 (e.g., electric ground or Vss). The FF 209 includes a PMOS transistor 208 having a drain coupled to a drain of an NMOS transistor 214, forming part of node N1. The FF 209 also includes a PMOS transistor 210 having a drain coupled to a drain of an NMOS transistor 218, forming part of node N2.

The gates of the PMOS transistor 208 and the NMOS transistor 214 are coupled to the node N2, and the gates of the PMOS transistor 210 and the NMOS transistor 218 are coupled to the node N1, as illustrated. In some implementations, a weight parameter for a neural network or other information may be stored in the FF 209 at nodes N1, N2 of each of the memory cells of the SRAM. The nodes N1, N2 represent the output and complementary output nodes of the FF 209, respectively.

As illustrated, the CIM circuit 200 may also include capacitive elements 270, 272 (respectively labeled “C” and “CB” in FIGS. 2A, 2B, and 2C). Capacitive element 270 may be coupled between the reference potential node 228 and a drain of an NMOS transistor 216. A source of the NMOS transistor 216 may be coupled to a first input (e.g., a positive input) of a processing and sensing circuit 234. The processing and sensing circuit 234 may be a sense amplifier (SA) or an ADC, for example. Capacitive element 272 may be coupled between the reference potential node 228 and a drain of an NMOS transistor 220. A source of the NMOS transistor 220 may be coupled to a second input (e.g., a negative input) of the processing and sensing circuit 234, as illustrated. The processing and sensing circuit 234 may be configured to process signals from the CIM circuit 200. Gates of NMOS transistors 216, 220 may be coupled to a read word-line (RWL), and sources of NMOS transistors 216, 220 may be coupled to a read bit-line (RBL) 260 and complementary RBL (RBLB) 262, respectively. The processing and sensing circuit 234 may be configured as an ADC that senses the differential signal between RBL 260 and RBLB 262, and provides a digital output of the CIM circuit 200.

During a computation phase, charge may be stored on the capacitive element 270 or the capacitive element 272 based on a weight parameter stored in the memory cell and activation signal of PCWL and PCWLB. For example, during computing operations, the PG switch 205 and the PG switch 207 may be turned on or off based on activation signal (e.g., via control activation signals PCWL 202 and/or PCWLB 204 output from controller 297), transferring the charge stored at node N1 or N2 to capacitive element 270 or 272. The PG switch 205 and PG switch 207 may then be turned off by controller 297 via the PCWL 202 and/or PCWLB 204. The controller 297 may then set the RWL to logic high to turn on NMOS transistors 216, 220. The NMOS transistors 216, 220 are turned on such that the processing and sensing circuit 234 senses the charge stored on capacitive element 270 and capacitive element 272. In other words, the processing and sensing circuit 234 senses the differential voltage between the RBL 260 and RBLB 262. In certain aspects, after the computation phase, capacitive elements 270 and/or 272 may be discharged via NMOS transistor 216 and/or NMOS transistor 220, respectively, to facilitate further CIM operations. For example, NMOS transistor 216 and NMOS transistor 220 may be turned on while the RBL and RBLB are coupled to a reference potential node by controller 297, effectively discharging the capacitive elements 270, 272.

During a write operation, the logic state at the RBL 260 and RBLB 262 may be set based on a weight parameter to be written to the memory cell. The controller 297 may turn on transistors 216, 220, and the switches 205, 207 may be closed (e.g., turned on) to set the voltages at nodes N1 and N2 of FF 209 based on the weight parameter, in effect writing the weight parameter in the memory cell. The transistors 216, 220 may then be turned off, and the switches 205, 207 may be opened (e.g., turned off).

FIG. 2D is a truth table 290 associated with the CIM circuit 200, in accordance with certain aspects of the present disclosure. As illustrated, the CIM circuit 200 performs an XNOR operation between the input at the PCWL (PCWLB) and the output node N1 (N2), the results of the XNOR operation being sensed via the RBL (RBLB). For example, when the PCWL is set to logic high (1) and node N1 is set to logic high (1), the RBL may be logic high. When the PCWL is set to logic high (1) and node N1 is set to logic low (0), then the RBL may be logic low (0), and the RBLB is set to logic high (1, or −1 since the RBLB is provided to the negative input of the processing and sensing circuit 234).

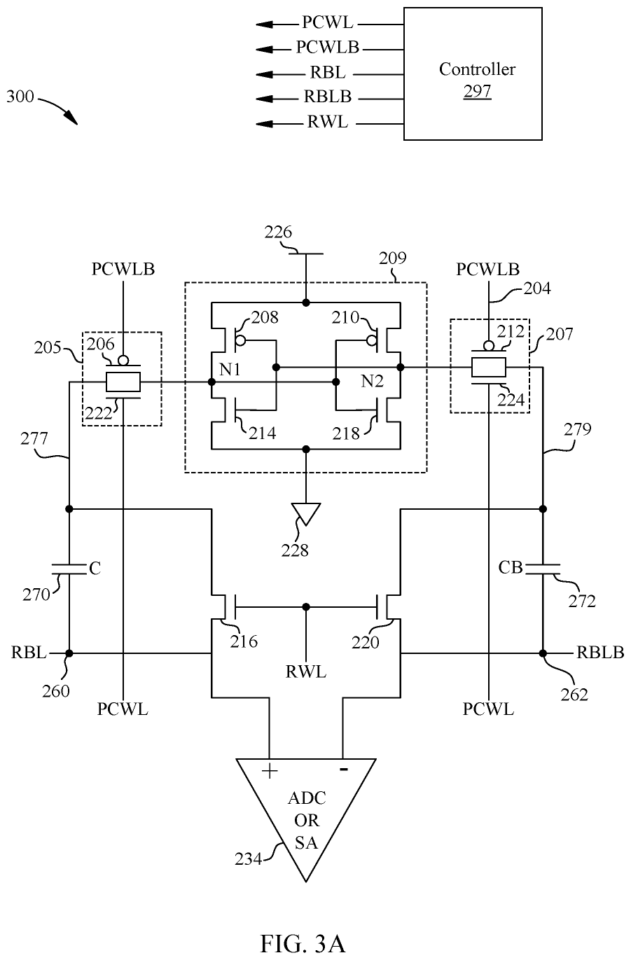

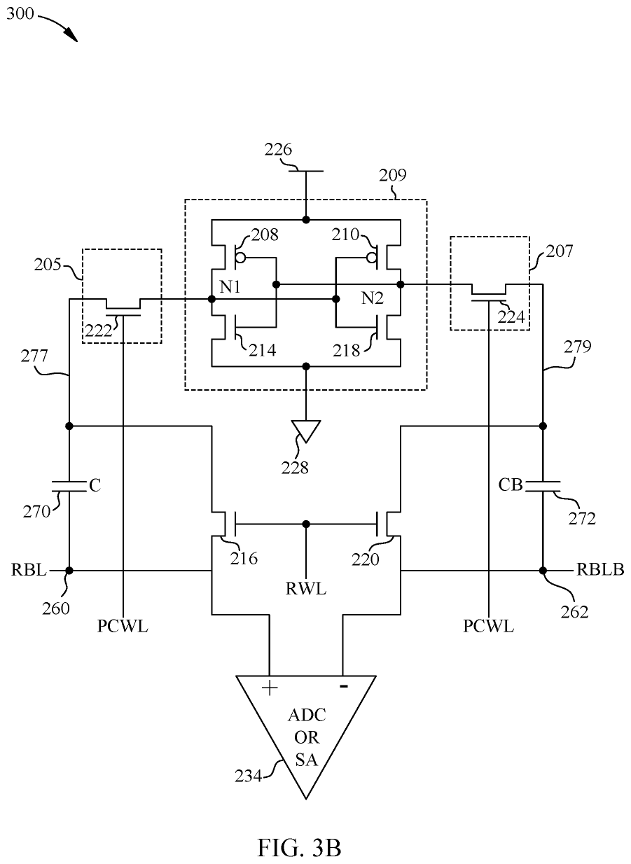

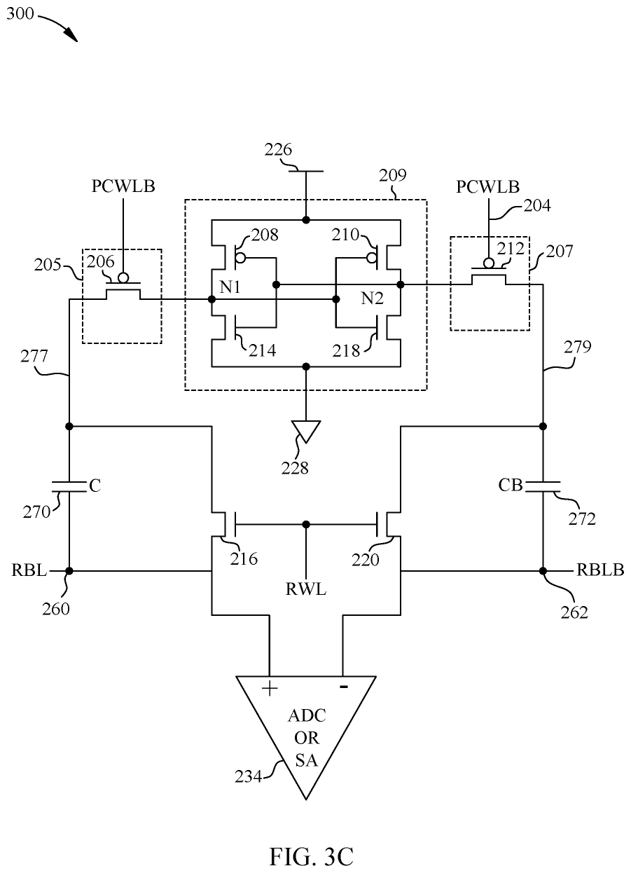

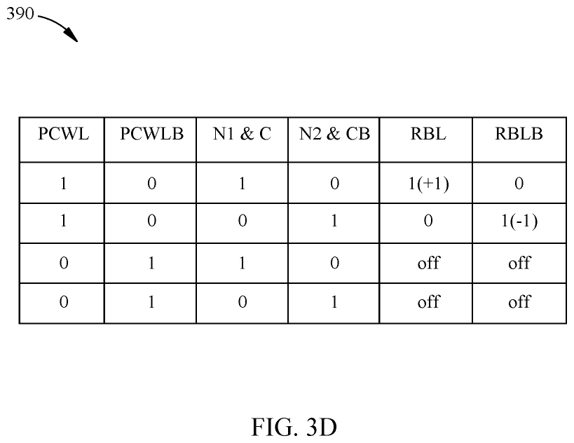

FIGS. 3A, 3B, and 3C illustrate a CIM circuit 300 implemented with capacitive elements coupled between PG switches and read bit lines, in accordance with certain aspects of the present disclosure. As illustrated, the capacitive element 270 may be coupled between the BL 277 and the RBL 260, and the capacitive element 272 may be coupled between the BLB 279 and the RBLB 262. In certain aspects, NMOS transistor 216 may be in parallel with capacitive element 270, and the NMOS transistor 220 may be in parallel with capacitive element 272. Similar to FIGS. 2A-2C, the switches 205, 207 may each be implemented using: both NMOS transistors 222, 224 and PMOS transistors 206, 212, respectively, as illustrated in FIG. 3A; NMOS transistors 222, 224, respectively, as illustrated in FIG. 3B; or PMOS transistors 206, 212, respectively, as illustrated in FIG. 3C.

During a computation phase, switches 205, 207 may be turned on via controller 297 by setting (e.g., via an XOR or XNOR computation activation data) the PCWL and/or PCWLB to logic high and/or logic low (activation), respectively. In some cases, the controller 297 may also couple the RBL and RBLB to a reference potential node and may control transistors 216, 220 to be off. In this configuration, the capacitive element 270 or 272 may be used for computation (e.g., charged) in accordance with the weight parameter stored at nodes N1 and N2 by activation of PCWL and PCWLB. At this stage, controller 297 may open (e.g., turn off) switches 205, 207 and may decouple the RBL and RBLB from the reference potential node. The processing and sensing circuit 234 may then sense the differential voltage between the RBL 260 and RBLB 262 and generate a digital output accordingly. In some aspects, the controller 297 may discharge the capacitive elements 270, 272 by turning on transistors 216, 220 via the RWL to facilitate further computations.

During a write phase, the logic states of the RBL and RBLB may be set based on the weight parameter to be written at nodes N1 and N2. The transistors 216, 220 may be then turned on by the controller 297 setting the RWL to logic high. The switches 205, 207 may be closed (e.g., turned on) to write the weight parameter at nodes N1 and N2. The transistors 216, 220 may be then turned off, and the switches 205, 207 may be opened (e.g., turned off).

FIG. 3D is a truth table 390 associated with the CIM circuit 300, in accordance with certain aspects of the present disclosure. As illustrated, the CIM circuit 300 performs an XNOR operation between the input at the PCWL (PCWLB) and the output node N1 (N2), the results of the XNOR operation being sensed via the RBL (RBLB). For example, when the PCWL is set to logic high (1) and node N1 is set to logic high (1), the RBL may be logic high. When the PCWL is set to logic high (1) and node N1 is set to logic low (0), then the RBL may be set to logic low (0), and the RBLB may be set to logic high (1, or −1 since RBLB is provided to the negative input of the processing and sensing circuit 234).

The RBL and RBLB may be coupled to multiple memory cells for CIM, the computation outputs of the memory cells being summed and converted to a digital signal by an ADC (e.g., processing and sensing circuit 234). For a single-ended CIM implementation, each CIM memory cell may be implemented using a single capacitive element. The voltage across the capacitive element may be sensed with reference to electric ground (or some other reference potential). As described herein, for a differential ADC implementation, two capacitive elements are used such that a differential voltage between the RBL and RBLB is sensed. The differential voltage may correspond to the difference between the voltages at the RBL and RBLB (e.g., RBL−RBLB). Therefore, the dynamic range of the CIM circuitry implemented with a differential ADC may be doubled, and the overall resolution may be improved, as compared to CIM circuitry implemented with a single-ended ADC.

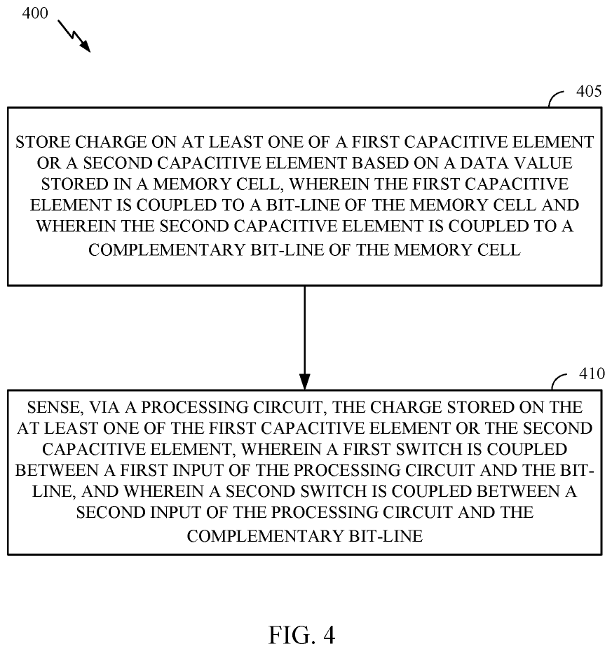

FIG. 4 is a flow diagram of example operations 400 for in-memory computation, in accordance with certain aspects of the present disclosure. The operations 400 may be performed by a memory system, such as the computation system 100 and CIM circuits 200, 300.

The operations 400 begin, at block 405, by storing charge on at least one of a first capacitive element (e.g., capacitive element 270) or a second capacitive element (e.g., capacitive element 272) based on a data value (e.g., a weight parameter or other information stored on nodes N1 and N2) stored in a memory cell, where the first capacitive element is coupled to a bit-line (e.g., BL 277) of the memory cell, and where the second capacitive element is coupled to a complementary bit-line (e.g., BLB 279) of the memory cell.

At block 410, the memory system senses, via a processing circuit (e.g., processing and sensing circuit 234), the computed charge stored on the at least one of the first capacitive element or the second capacitive element. In certain aspects, a first switch (e.g., NMOS transistor 216) may be coupled between a first input of the processing circuit and the bit-line, and a second switch (e.g., NMOS transistor 220) may be coupled between a second input of the processing circuit and the complementary bit-line.

In certain aspects, the memory system may also discharge the at least one of the first capacitive element or the second capacitive element via the first switch or the second switch. In some aspects, the memory system may provide the data value to at least one of a read bit-line (e.g., RBL 260) coupled to the first switch or a complementary read bit-line (e.g., RBLB 262) coupled to the second switch, and write the data value in the memory cell by closing at least one of the first switch or the second switch.

In some aspects, the memory cell may include an SRAM memory cell having a FF (e.g., FF 209), a first PG switch (e.g., PG switch 205) coupled between the bit-line and the FF, and a second PG switch (e.g., PG switch 207) coupled between the complementary bit-line and the FF. In this case, the writing of the data value may also include closing the first PG switch and the second PG switch. In some aspects, the sensing of the charge at block 410 may include closing the first switch and the second switch.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes, and variations may be made in the arrangement, operation, and details of the methods and apparatus described above without departing from the scope of the claims.

1. A circuit for in-memory computation, comprising:
a memory cell having a bit-line and a complementary bit-line, wherein the memory cell includes a flip-flop (FF), a first pass-gate (PG) switch, and a second PG switch;
a first capacitive element coupled to the bit-line;
a second capacitive element coupled to the complementary bit-line;
a processing circuit;
a first switch coupled between a first input of the processing circuit and the bit-line; and
a second switch coupled between a second input of the processing circuit and the complementary bit-line, wherein the first PG switch is connected between the first capacitive element and the FF, and wherein the second PG switch is connected between the second capacitive element and the FF.

2. The circuit of claim 1, wherein:
the first capacitive element is coupled between the bit-line and a reference potential node; and
the second capacitive element is coupled between the complementary bit-line and the reference potential node.

3. The circuit of claim 1, wherein:
the first capacitive element is coupled between the bit-line and the first input of the processing circuit; and
the second capacitive element is coupled between the complementary bit-line and the second input of the processing circuit.

4. The circuit of claim 3, wherein:
the first switch is coupled in parallel with the first capacitive element; and
the second switch is coupled in parallel with the second capacitive element.

5. The circuit of claim 1, wherein the memory cell comprises a static random access memory (SRAM).

6. The circuit of claim 1, wherein each of the first PG switch and the second PG switch comprises:
an n-type metal-oxide-semiconductor (NMOS) transistor;
a p-type metal-oxide-semiconductor (PMOS) transistor; or
an NMOS transistor coupled in parallel with a PMOS transistor.

7. The circuit of claim 1, further comprising a controller configured to store charge on the first capacitive element and the second capacitive element based on a data value stored in the memory cell, wherein the processing circuit is configured to sense the charge stored on the first capacitive element and the second capacitive element.

8. The circuit of claim 7, wherein the controller is further configured to discharge at least one of the first capacitive element or the second capacitive element via the first switch or the second switch, respectively.

9. The circuit of claim 7, wherein the controller is further configured to:
provide the data value to a read bit-line coupled to the first switch or a complementary read bit-line coupled to the second switch; and
write the data value in the memory cell by closing at least one of the first switch or the second switch.

10. The circuit of claim 9, wherein:
the memory cell further comprises a static random access memory (SRAM);
the first PG switch is coupled between the bit-line and the FF;
the second PG switch is coupled between the complementary bit-line and the FF; and
the controller is configured to write the data value by closing at least one of the first PG switch or the second PG switch.

11. The circuit of claim 1, wherein at least one of the first capacitive element or the second capacitive element is configured to be discharged via the first switch or the second switch, respectively.

12. The circuit of claim 1, wherein the processing circuit comprises an analog-to-digital converter (ADC).

13. The circuit of claim 1, wherein the processing circuit comprises a sense amplifier.

14. A method for in-memory computation, comprising:
storing charge on at least one of a first capacitive element or a second capacitive element based on a data value stored in a memory cell, wherein the memory cell includes a flip-flop (FF), a first pass-gate (PG) switch, and a second PG switch, wherein the first capacitive element is coupled to a bit-line of the memory cell, and wherein the second capacitive element is coupled to a complementary bit-line of the memory cell; and
sensing, via a processing circuit, the charge stored on the at least one of the first capacitive element or the second capacitive element, wherein a first switch is coupled between a first input of the processing circuit and the bit-line, wherein a second switch is coupled between a second input of the processing circuit and the complementary bit-line, wherein the first PG switch is connected between the first capacitive element and the FF, and wherein the second PG switch is connected between the second capacitive element and the FF.

15. The method of claim 14, further comprising discharging the at least one of the first capacitive element or the second capacitive element via the first switch or the second switch, respectively.

16. The method of claim 14, further comprising:
providing the data value to at least one of a read bit-line coupled to the first switch or a complementary read bit-line coupled to the second switch; and
writing the data value in the memory cell by closing at least one of the first switch or the second switch.

17. The method of claim 16, wherein:
the memory cell comprises a static random access memory (SRAM);
the first PG switch is coupled between the bit-line and the FF;
the second PG switch is coupled between the complementary bit-line and the FF; and
writing the data value further comprises closing the first PG switch and the second PG switch.

18. The method of claim 14, wherein the sensing of the charge comprises closing the first switch and the second switch.

19. The method of claim 14, wherein the processing circuit comprises an analog-to-digital converter (ADC).

20. The method of claim 14, wherein storing the charge on at least one of the first capacitive element or the second capacitive element is based on an exclusive OR (XOR) or exclusive NOR (XNOR) computation activation data.
